(19) United States
(12) Patent Application Publication
(10) Pub. No.: US 2004/0218767 A1
(43) Pub. Date: Nov. 4, 2004

(54) Surround sound methods and apparatus for improving auditory processing and increasing spatial awareness

(76) Inventors: G. Alexander Doman, Ogden, UT (US); Richard O. Lawrence, Ogden, UT (US)

Correspondence Address: KIRTON & McCONKIE, 1800 Eagle Gate Tower, 60 East South Temple, Salt Lake City, UT, 84111, US

(21) Appl. No.: 10/422,266

(22) Filed: Apr. 24, 2003

(51) Int. Cl. H03G 5/00; H04R 25/00

(52) U.S. Cl. 381/98; 381/320

(57) ABSTRACT

A method and system for improving auditory processing and increasing spatial awareness, wherein the voices of a musical composition are arranged, recorded and produced in particular combinations and at particular frequency levels according to a predetermined program designed to exercise auditory muscles, imprint the frequency map, and stimulate dendritic growth and synaptic organization.

### BACKGROUND OF THE INVENTION

1. Field of the Invention

The present invention relates to a method and system for improving auditory processing and increasing spatial awareness, and more particularly to a method and system for arranging, recording and presenting discrete sounds in particular combinations and at particular frequency levels according to a predetermined program designed to exercise auditory muscles, imprint the frequency map, and stimulate dendritic growth and synaptic organization.

2. Background and Related Art

Auditory processing encompasses sound perception as well as frequency sorting, localization, attention, analysis, storage and retrieval, auditory discrimination, comprehension, and auditory synthesis and generalization. Effective auditory processing is thus essential to speech, language, reading, writing and the ability to learn and retain new information.

Effective auditory processing may be developed even before infancy as a child is exposed to sounds and vibrations in utero. Likewise, auditory processing disorders such as auditory figure-ground, auditory decoding problems, auditory temporal processing deficits, auditory memory difficulties and auditory integration problems may arise as early as infancy and early childhood. Indeed, an estimated eight to twelve million children in the United States suffer from learning disabilities at least partially attributable to auditory processing disorders.

The auditory process begins when an auditory stimulus, or sound wave, is received by the outer ear and channeled into the auditory canal, where it causes vibration of the tympanic membrane. Such airborne vibrations are transferred by the malleus, incus and stapes, the three bones of the middle ear, to the oval window of the cochlea, or inner ear. The middle ear muscles, tensor tympani and stapedius, attach to the malleus and stapes for both fixation and protection. The muscles contract in response to loud sounds, thereby decreasing the effectiveness of transmission of intense vibrations and protecting the cochlea.

It is in the cochlea that transduction of sound energy into neural activity takes place. Indeed, hair cells present in the cochlea excite neurons of the spinal ganglion, thereby initiating conduction of auditory information into the brain and ultimately into the auditory cortex, where language and sounds are coded, organized, interpreted and understood.

Many methods for enhancing and/or improving this auditory processing pathway are presently known.

For example, U.S. Pat. No. 5,782,873 to Collins (“Collins”) discloses a method and system for enhancing the function of sensory cells wherein a sensory cell area associated with the sensory cell whose function is to be enhanced is located. A bias signal is then applied to the sensory cell area, thus effectively lowering the threshold of sensory cells with which the sensory cell area is associated. Thus, as applied to the auditory system, Collins teaches probing an area of the cochlea containing hair cells with an electrode or other input means carrying a bias signal to artificially cause the hair cells to excite neurons of the spinal ganglion.

Although Collins discloses that the above system may be applied to enhance the sensory function of healthy individuals as well as those exhibiting sensory related disorders or disease, the invasiveness and artificiality of the Collins system is unlikely to appeal to the public at large, especially to healthy individuals, children, and individuals only moderately affected by a sensory-related disorder.

Accordingly, what is needed is a non-invasive system to improve and/or enhance auditory processing that appeals to individuals with sensory deficits as well as to healthy individuals. What is also needed is a system to enhance auditory processing that is appropriate for use by children. Further what is needed is an auditory enhancing system that does not require professional application or supervision.

Such methods and systems for enhancing auditory processing are disclosed and claimed herein.

### SUMMARY OF THE INVENTION

The present invention is a non-invasive system for improving auditory processing and increasing spatial awareness. The system implements a sound-based program having three sequential tracks. The individual voices of such tracks are introduced across a 360 degree spatial field to increase spatial awareness by facilitating voice isolation and perception. The first track presents full spectrum sound gradually blended into a stream of filtered sound of relatively low complexity. The second track intersperses bursts of medium to high complexity filtered sound into a background of relatively low complexity filtered sound. The third track again presents the relatively low complexity filtered sound of the first track, while gradually incorporating streams of unfiltered sound and decreasing the filtered track until the original full spectrum sound returns. In this manner, the auditory pathway is allowed to gradually become accustomed to sounds of increasing complexity, systematically be exposed to high complexity sound, and then gradually recover. This system of auditory therapy relies on principles of neural plasticity to improve dendritic growth and establish and strengthen neural pathways related to auditory processing. Further, the recovery phase of therapy enables a listener to become reintroduced to normal environmental sounds without experiencing undue agitation or discomfort.

An object of the present invention is to provide a system for improving auditory processing in individuals with auditory processing disorders, as well as enhancing auditory processing in healthy individuals.

Another object of the present invention is to provide a non-invasive sound based system for improving auditory processing that is capable of accommodating infants and very young children as well as adults.

A further object of the present invention is to provide a system for improving auditory processing that relies on principles of neural plasticity to create and strengthen neural pathways and to improve dendritic growth.

Another object of the present invention is to provide a system for improving auditory processing and function that does not require professional application or supervision.

These and other features and advantages of the present invention will be set forth or will become more fully apparent in the description that follows. The features and advantages may be realized and obtained by means of the instruments and combinations particularly pointed out in the appended claims. Furthermore, the features and advantages of the invention may be learned by the practice of the invention or will be obvious from the description, as set forth hereinafter.

### BRIEF DESCRIPTION OF THE DRAWINGS

The foregoing and other objects and features of the present invention will become more fully apparent from the following description and appended claims, taken in conjunction with the accompanying drawings. Understanding that these drawings depict only typical embodiments of the invention and are, therefore, not to be considered limiting of its scope, the invention will be described and explained with additional specificity and detail through the use of the accompanying drawings in which:

FIG. 1 is a cross-sectional view of the physiological organs, bones and muscles involved in auditory processing;

FIG. 2 is a perspective view of the brain indicating the location of the auditory cortex;

FIG. 3 is a flow chart delineating the relationship between the tracks of the present invention;

FIG. 4 is a diagram of the relative intensities and complexities exposed to the auditory pathway during the phases taught by the present invention; and

FIG. 5 is a diagram of filtration and audio bursting specifications for use with selected embodiments of the present invention.

### DETAILED DESCRIPTION OF THE INVENTION

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes that come within the meaning and range of equivalency of the claims are to be embraced within their scope.

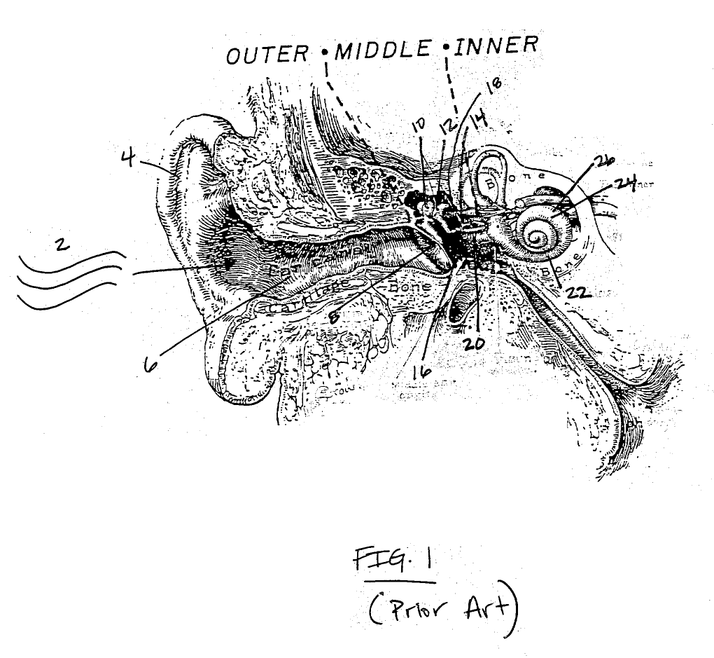

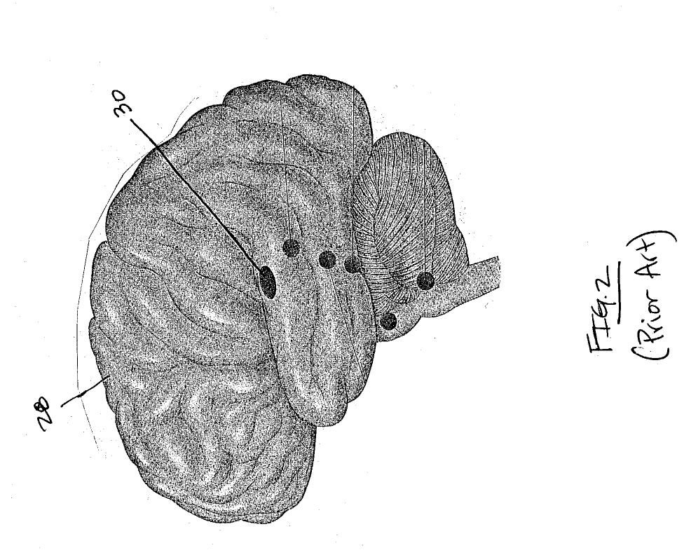

As used in this specification, the term “full spectrum sound” refers to the audible spectrum of sound in a range from about 0 Hz to about 20,000 Hz having no frequencies omitted. The term “hertz” refers to the international unit of frequency equal to one oscillation per second. The term “decibel level” refers to a unit of ratios of power levels, which may be used for measuring relative loudness of sound. The term “graduated curve” indicates a transition period of about two minutes from full spectrum sound to a filter reaching maximum level. The term “medium curve” indicates a transition period of about one and one half minutes from full spectrum sound to a filter reaching maximum level. Finally, the term “steep curve” indicates a transition period of about one minute from full spectrum sound to a filter reaching maximum level. Referring to FIG. 1, the human central auditory process originates with a sound wave 2 received by an outer ear 4. The sound wave 2 is channeled into the auditory canal 6, where it causes vibration of the tympanic membrane 8. The malleus 10, the largest of the ossicles of the middle ear, is attached to the tympanic membrane 8 such that vibration of the tympanic membrane 8 is effectively transferred to the ossicular structure comprising the malleus 10, incus 12 and stapes 14. The foot plate of the stapes 14 transfers the vibration into the oval window 20 of the cochlea 22, where the sound wave 2 to be transduced to neural activity. More specifically, hair cells 24 present in the cochlea 22 excite neurons of the spinal ganglion 26 contained within the cochlea 22. Such neurons transmit auditory information into the brain 28, depicted in FIG. 2, via the auditory nerve, and ultimately into the auditory cortex 30, where language and sounds are coded, organized, interpreted and understood.

Competent auditory processing thus requires an intact auditory signal 2, an intact ear 4, an intact auditory nerve, and a brain capable of receiving auditory information and acting upon it in a meaningful way. Any or all of these critical components may be compromised by any number of genetic and/or environmental factors. For example, some cases of auditory processing disorders are caused by malfunctioning blood vessels or nerves that serve the brain resulting from stroke, viruses, head injuries, Parkinson's disease, autism or as a result of taking certain medications. Other causes of auditory processing disorders include chronic otitis media, lead poisoning and anoxia. Still other causes include a lack of oxygen at birth and/or failure of embryological development. Although individuals suffering from auditory processing related disorders may experience deficiencies in any one or all of the physiological components necessary for proper auditory processing, improved auditory processing in any individual may be accomplished by implementing the system and method herein disclosed.

The present invention provides a novel system and method for improving and/or enhancing auditory processing that relies on the ability of some parts of the nervous system, like the brain and auditory processing pathways, to modify their functional characteristics in response to certain stimuli over time. Indeed, the present invention exploits the principles of neural plasticity, which forms the basis of learning.

Specifically, the method and system of the present invention comprises arranging, recording and producing musical compositions in a manner that retains the discreteness of individual tonal voices while uniquely filtering and combining voices and tones to permit varied exercises in sound localization.

The present invention also contemplates organizing the exercises according to an acclimatization or warm-up period for gradually introducing more complex sound, an exercise period where the complexity of the sound is increased and short bursts of high complexity sound in varied spatial arrangements are intermittently interspersed, and a recovery period where full spectrum sound is gradually reintroduced. It has been determined that this method of organization enables sensitization of an individual to an auditory stimulus such that the individual may thereafter experience an increase in responsiveness to an auditory stimulus that previously may have been too weak to elicit a response. Although the way in which this is accomplished is not entirely understood, it is believed that frequent exposure to complex sounds and spatial arrangements in combination with periods of rest exercises auditory muscles, strengthens neural pathways and improves dendritic growth resulting in an increased ability to discern and locate sound. In essence, the present invention enables an individual to learn how to better perceive and locate sound over time.

Specifically, the method of the present invention contemplates arranging a musical composition in an unusually varied way such that independent tonal lines, such as melody and harmony, may be implemented in series over several voices. For example, a melody may be played by a clarinet for eight measures, and then picked up by a flute for the next eight measures. Likewise, a bass line may be played by a cello for the first four measures, and then picked up by a bassoon. Arranging a musical composition in this manner, together with unique spatial treatments, enhances an effect of spatial stimulation upon a listener.

An arrangement may then be recorded in isolated tracks and formatted such that each voice is retained in isolation on a single track and may be reproduced in mono, stereo, or multichannel form, such as Dolby 5.1 Surround Sound. Recording in this manner enables each voice to maintain its distinctness and directionality, whether played back as an isolated voice, or mixed with other voices to create a composite voice. Although a multi-speaker or headphone surround sound apparatus is preferable for use with the present invention, other suitable technologies known to those in the art may be used.

Spatial characteristics and arrangements of voices may be enhanced by altering the timing between channels, altering the relative intensity of channels, and altering the relative filters applied to the voices subsequent to recording. In this way, a listener may perceive a variety of spatial arrangements to enhance spatial stimulation and better process the spatial source of sound.

Yet another embodiment utilizes a dynamic variation of this theme by rotating or switching channels to produce the impression that the instruments are moving about the room.

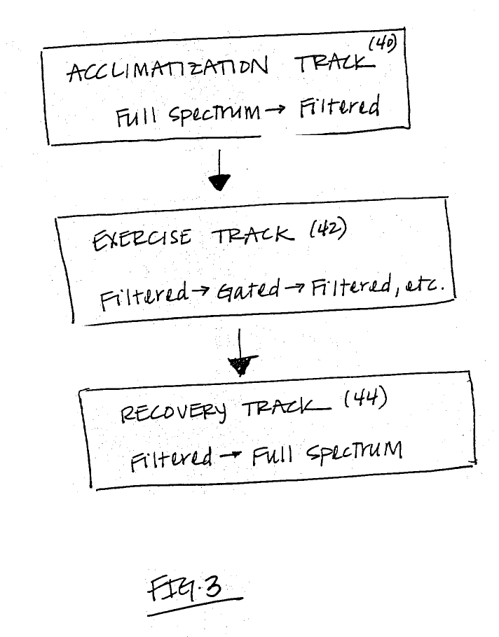

Traditional multi-channel sound recordings utilize only a narrow spatial view of approximately 60 degrees in which to introduce voices. The remaining 300 degrees are utilized entirely for reflective elements of the voices. This imbalanced spatial arrangement results in auditory fatigue and reduced spatial stimulation as the listener must artificially isolate sounds in order to properly process and perceive such auditory information. In addition, traditional formatting techniques fail to encourage development of a listener's ability to process the spatial source of sound. Certain embodiments of the present invention, on the other hand, format a musical arrangement such that a listener perceives the voices as if he is situated in the middle of them, thus perceiving auditory stimuli from in front, behind, and to any side of him within a 360 degree radius. Such formatting greatly enhances the effect of spatial stimulation and avoids auditory fatigue resulting from the strain of having to artificially isolate sounds. In addition, certain embodiments of the present invention introduce higher frequency sounds to the right ear and lower frequency sounds to the left ear, in accordance with the way in which the majority of people naturally process sound. In this way, the present invention again enables a listener to better process the spatial source of sound while avoiding undue auditory fatigue and loss of stimulation. A voice or composite voice may then be filtered according to specific parameters depending on its place within an audio program 96 as a whole. For example, referring now to FIG. 3, one embodiment of the present invention teaches an audio program 96 comprising three sequential tracks for improving auditory processing. A first track may comprise an acclimatization track 40, wherein full spectrum sound may be gradually filtered to a filtered sound comprising only a portion of the audible spectrum of sound. A second track may comprise an exercise track 42, wherein a filtered sound may be periodically interrupted by an audio bursted sound within a certain frequency range, for example 2000 Hz to 3000 Hz. A third track may comprise a recovery track 44, wherein a filtered sound is gradually reintroduced into full spectrum sound.

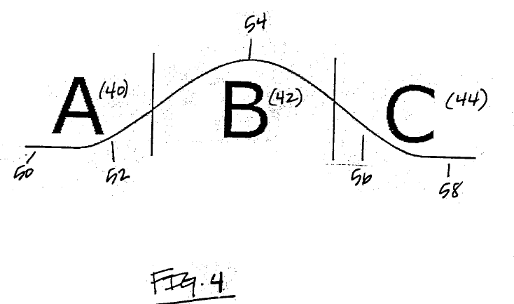

Referring now to FIG. 4, an acclimatization track 40, exercise track 42, and recovery track 44 may be arranged in such a way as to gradually introduce more complex sounds and spatial exercises while providing a sufficient period of time to recover from such stimuli. In one embodiment of the present invention, an acclimatization track devotes a first half of the track time to full spectrum sound 50, which sound is gradually filtered to reach a first filtered sound 52.

A first filtered sound 52 may also be used to introduce the exercise track 42. Alternatively, the exercise track 42 may begin with a second filtered sound 60 that may be either more or less filtered than the first filtered sound 52. The exercise track 42 may retain the first or second filtered sound levels 52 or 60 to provide a background for a range of audio bursted sound 62 that may be intermittently interspersed over the background. In one embodiment of the present invention, an audio bursted sound 62 is in a range from 2000 Hz to 3000 Hz. A frequency level for an audio bursted sound 62 is preferably increased as the exercise track 42 reaches its midpoint 54, after which the frequency level of an audio bursted sound 62 may be gradually decreased. Similarly, channels may be rotated or exchanged to create the perception that the instruments are moving. After a period of movement, the channels will return to their original stationary configuration.

A recovery track 44 may begin with a first filtered sound 52. This filtered sound may be progressively absorbed into the initial full spectrum sound 50 of the acclimatization track 40. In this way, a listener is gradually reintroduced to normal frequency range random sound and noise of everyday life without experiencing undue agitation or discomfort.

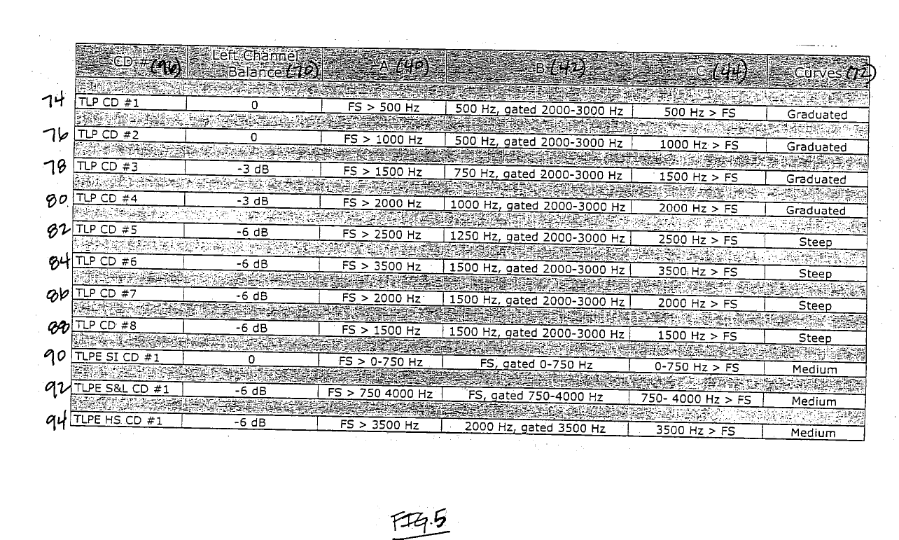

Referring now to FIG. 5, in addition to the acclimatization track 40, exercise track 42 and recovery track 44 discussed supra, an audio program 96 may also comprise a volume level 70 and a slope type 72. A volume level 70 may correspond to the relative loudness of a full spectrum sound 50 used in an audio program 96. Higher volume levels 70 may be implemented to accommodate a novice listener, or a listener affected by an auditory processing disorder. A volume level 70 may be decreased as successive audio programs 96 are implemented and a listener learns greater sensitivity to auditory stimuli. In addition, volume levels 70 may be channel and/or speaker specific such that, for example, a volume level 70 corresponding to one channel may be decreased relative to a volume level 70 corresponding to a second channel in order to emphasize the voice corresponding to the second channel.

A slope type 72 may also be varied according to the sophistication and experience of a listener. A graduated slope type refers to a transition time of approximately two minutes between full spectrum sound 50 and a first filtered sound 52. A graduated slope type is thus a relatively slow and calculated transition period appropriate for novice listeners, infants and children, and listeners affected by an auditory processing disorder. A medium slope type refers to a transition time of approximately one and one half minutes between full spectrum sound 50 and a first filtered sound level 52. A medium slope type is thus appropriate for amateur listeners, older children and adults, and listeners only slightly affected by an auditory processing disorder. A steep slope type indicates a transition time of approximately one minute between full spectrum sound 50 and a first filtered sound level 52. Accordingly, a steep slope type is appropriate for experienced listeners.

The volume level 70 and slope type 72 may be adjusted according to a predetermined audio program plan. For example, a relatively high volume level 70, 0 dB for example, and graduated slope type 72 may be implemented in the first audio program 96 of a three part series. A second audio program may then reduce the volume level 70 to an intermediate level, for example −3 dB, and increase the slope type 72 to medium. A third audio program may reduce the volume level 70 still further, to −6 dB for example, and implement a steep slope type 72. In this manner, a listener may be systematically exposed to complex sounds and spatial arrangements requiring increasing sensitivity to auditory information. Likewise, a listener may personalize a plan according to their individual stage of auditory development.

What is claimed is:

1. An audio device for improving auditory processing and increasing spatial awareness, said device comprising:
a readable medium for storing an audio program, wherein said audio program comprises:
an acclimatization track for gradually reducing full spectrum sound to a first filtered sound;
an exercise track for intermittently interspersing an audio bursted sound into a second filtered sound, and
a recovery track for gradually mixing said first filtered sound with said full spectrum sound;
a playback device for reading said readable medium; and
an output device for producing an audio output signal corresponding to said audio program.

2. The audio device of claim 2, wherein said first filtered sound comprises about 500 Hz.

3. The audio device of claim 2, wherein said second filtered sound comprises about 500 Hz and wherein said gated sound comprises a range from about 2000 Hz to about 3000 Hz.

4. The audio device of claim 2, wherein said first filtered sound comprises about 1000 Hz.

5. The audio device of claim 4, wherein said second filtered sound comprises about 500 Hz and wherein said gated sound comprises a range from about 2000 Hz to about 3000 Hz.

6. The audio device of claim 2, wherein said first filtered sound comprises about 1500 Hz.

7. The audio device of claim 6, wherein said second filtered sound comprises about 750 Hz and wherein said gated sound comprises a range from about 2000 Hz to about 3000 Hz.

8. The audio device of claim 2, wherein said first filtered sound comprises about 2000 Hz.

9. The audio device of claim 8, wherein said second filtered sound comprises about 1000 Hz and wherein said gated sound comprises a range from about 2000 Hz to about 3000 Hz.

10. The audio device of claim 2, wherein said first filtered sound comprises about 2500 Hz.

11. The audio device of claim 10, wherein said second filtered sound comprises about 1250 Hz and wherein said gated sound comprises a range from about 2000 Hz to about 3000 Hz.

12. The audio device of claim 2, wherein said first filtered sound comprises about 3500 Hz.

13. The audio device of claim 12, wherein said second filtered sound comprises about 1500 Hz and wherein said gated sound comprises a range from about 2000 Hz to about 3000 Hz.

14. The audio device of claim 12, wherein said second filtered sound comprises about 2000 Hz and wherein said gated sound comprises about 3500 Hz.

15. The audio device of claim 2, wherein said first filtered sound comprises a range from about 0 Hz to about 750 Hz.

16. The audio device of claim 15, wherein said second filtered sound comprises full spectrum sound and wherein said gated sound comprises a range from about 0 Hz to about 750 Hz.

17. The audio device of claim 2, wherein said first filtered sound comprises a range from about 750 Hz to about 4000 Hz.

18. The audio device of claim 17, wherein said second filtered sound comprises full spectrum sound and wherein said gated sound comprises a range from about 750 Hz to about 4000 Hz.

19. The audio device of claim 2, wherein said audio program further comprises a volume level corresponding to a volume of said full spectrum sound.

20. The audio device of claim 19, wherein said volume level is selected from the group consisting of 0 dB, −3 dB and −6 dB.

21. The audio device of claim 2, wherein said audio program further comprises a slope type corresponding to a transition time between said full spectrum sound and said first filtered sound.

22. The audio device of claim 21, wherein said slope type is selected from the group consisting of graduated, medium and steep.

23. A readable medium for storing an audio program capable of improving auditory processing and increasing spatial awareness, said readable medium comprising:
a first track comprising full spectrum sound gradually filtered to produce a first filtered sound;
a second track comprising a second filtered sound, wherein an
audio bursted sound is intermittently interspersed with said second filtered sound; and
a third track comprising said first filtered sound gradually mixing with said full spectrum sound.

24. The readable medium of claim 23, wherein said first filtered sound comprises about 500 Hz.

25. The readable medium of claim 23, wherein said second filtered sound comprises about 500 Hz and wherein said audio bursted sound comprises a range from about 2000 Hz to about 3000 Hz.

26. The readable medium of claim 23, wherein said first filtered sound comprises about 1000 Hz.

27. The readable medium of claim 26, wherein said second filtered sound comprises about 500 Hz and wherein said audio bursted sound comprises a range from about 2000 Hz to about 3000 Hz.

28. The readable medium of claim 23, wherein said first filtered sound comprises about 1500 Hz.

29. The readable medium of claim 28, wherein said second filtered sound comprises about 750 Hz and wherein said audio bursted sound comprises a range from about 2000 Hz to about 3000 Hz.

30. The readable medium of claim 23, wherein said first filtered sound comprises about 2000 Hz.

31. The readable medium of claim 30, wherein said second filtered sound comprises about 1000 Hz and wherein said audio bursted sound comprises a range from about 2000 Hz to about 3000 Hz.

32. The readable medium of claim 23, wherein said first filtered sound comprises about 2500 Hz.

33. The readable medium of claim 32, wherein said second filtered sound comprises about 1250 Hz and wherein said audio bursted sound comprises a range from about 2000 Hz to about 3000 Hz.

34. The readable medium of claim 23, wherein said first filtered sound comprises about 3500 Hz.

35. The readable medium of claim 34, wherein said second filtered sound comprises about 1500 Hz and wherein said audio bursted sound comprises a range from about 2000 Hz to about 3000 Hz.

36. The readable medium of claim 34, wherein said second filtered sound comprises about 2000 Hz and wherein said audio bursted sound comprises about 3500 Hz.

37. The readable medium of claim 23, wherein said first filtered sound comprises a range from about 0 Hz to about 750 Hz.

38. The readable medium of claim 37, wherein said second filtered sound comprises full spectrum sound and wherein said audio bursted sound comprises a range from about 0 Hz to about 750 Hz.

39. The readable medium of claim 23, wherein said first filtered sound comprises a range from about 750 Hz to about 4000 Hz.

40. The readable medium of claim 39, wherein said second filtered sound comprises full spectrum sound and wherein said gated sound comprises a range from about 750 Hz to about 4000 Hz.

41. The readable medium of claim 23 further comprising a volume level corresponding to a volume of said full spectrum sound.

42. The readable medium of claim 41, wherein said volume level is selected from the group consisting of 0 dB, −3 dB and −6 dB.

43. The readable medium of claim 23, further comprising a slope type corresponding to a transition time between said full spectrum sound and said first filtered sound.

44. The readable medium of claim 43, wherein said slope type is selected from the group consisting of graduated, medium and steep.

45. A method for improving auditory processing and increasing spatial awareness, said method comprising the steps of:
arranging a musical composition to enhance perception of spatial relationships, wherein said musical composition comprises a plurality of instruments;
recording each of said plurality of voices onto an independent channel;
combining said channels to create a composite;
dynamically recombining said channels to produce the perception that the instruments are moving to different spatial locations; and
providing an audio output signal corresponding to said channels,
wherein said audio output signal enhances said user's ability to process auditory information and localize sound.
